(19) United States
(12) Patent Application Publication
(10) Pub. No.: US 2012/0052630 A1
(43) Pub. Date: Mar. 1, 2012

(54) METHOD FOR MANUFACTURING CHIP PACKAGE

(76) Inventors: Chang-Chih LIN, Hsinchu (TW); Shou-Chian Hsu, Hsinchu (TW); Kuo-Yu Yeh, Hsinchu (TW); Chun-Hsing Su, Hsinchu (TW)

(21) Appl. No.: 13/069,894

(22) Filed: Mar. 23, 2011

(30) Foreign Application Priority Data
Aug. 27, 2010 (TW) 099128762

(51) Int. Cl. H01L 21/60

(52) U.S. Cl. 438/108; 257/E21.506

(57) ABSTRACT

A method for manufacturing a chip package includes exposing a ground ring out of encapsulating material in a direct or indirect way and forming a conductive film electrically connected to the ground ring so as to form an EMI shield and prevent external EMI. The present invention also massively forms conductive film for package structure for lowering the complexity and cost of manufacturing processes.

### BACKGROUND OF THE INVENTION

1. Field of the Invention

The present invention relates to a method for manufacturing chip package, more particularly to a method for manufacturing chip package by forming a conductive film electrically connected to a ground ring.

2. Description of the Prior Art

EMI (electromagnetic interference) within an electronic system has been a common issue due to tendency of smaller size of the electronic system as well as higher density of electronic components within the system. In addition, certain package structures such as RF (radio frequency) chip package structures are likely to be interfered by EMI. Therefore, development of methods and equipments for decreasing interference caused by EMI so as to decrease synergistic EMI effect is now a current issue.

External cases for masking electromagnetic wave have been designed and provided for decreasing EMI. However, additional external cases would have disadvantages such as higher cost and more complex manufacturing process.

To sum up, development of a novel method for decreasing EMI is still needed for now.

### SUMMARY OF THE INVENTION

The present invention is directed to a method for manufacturing a chip package by forming a conductive film electrically connected to the ground ring so as to form an EMI shield and prevent external EMI. The present invention also massively forms conductive film for package structure for lowering the complexity and cost of manufacturing processes.

According to an embodiment, a method for manufacturing chip package includes providing a chip mounting device having a plurality of chip mounting units arrayed thereon, wherein each chip mounting unit is provided with a ground ring configured on an upper surface of the chip mounting unit; respectively mounting each chip on the upper surface of each chip mounting unit and electrically connecting the chip to the upper surface of each chip mounting unit; covering the ground ring and the chip on each chip mounting unit with an encapsulating material; partially removing the encapsulating material so as to expose a part of the ground ring; forming a conductive film covering the encapsulating material and the exposed ground ring; and singulating the chip mounting device to obtain each separated chip mounting unit.

According to the other embodiment of the present invention, a method for manufacturing chip package includes providing a chip mounting device having a plurality of chip mounting units arrayed thereon, wherein each chip mounting unit is provided with a ground ring configured on an upper surface of the chip mounting unit and the ground rings of adjacent chip mounting units are electrically connected to each other via a wire; respectively mounting each chip on the upper surface of each chip mounting unit and electrically connecting the chip to the upper surface of each chip mounting unit; covering the ground ring, the chip and the wire associated with each chip mounting unit with an encapsulating material; singulating the chip mounting device to obtain each separated chip mounting unit and expose a part of the wire; and forming a conductive film covering the encapsulating material and the exposed wire.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIGS. 1a-1d are side-view diagrams illustrating a method for manufacturing a chip package according to one embodiment of the present invention, and

FIGS. 2a-2c are side-view diagrams illustrating a method for manufacturing a chip package according to another embodiment of the present invention.

### DESCRIPTION OF THE PREFERRED EMBODIMENT

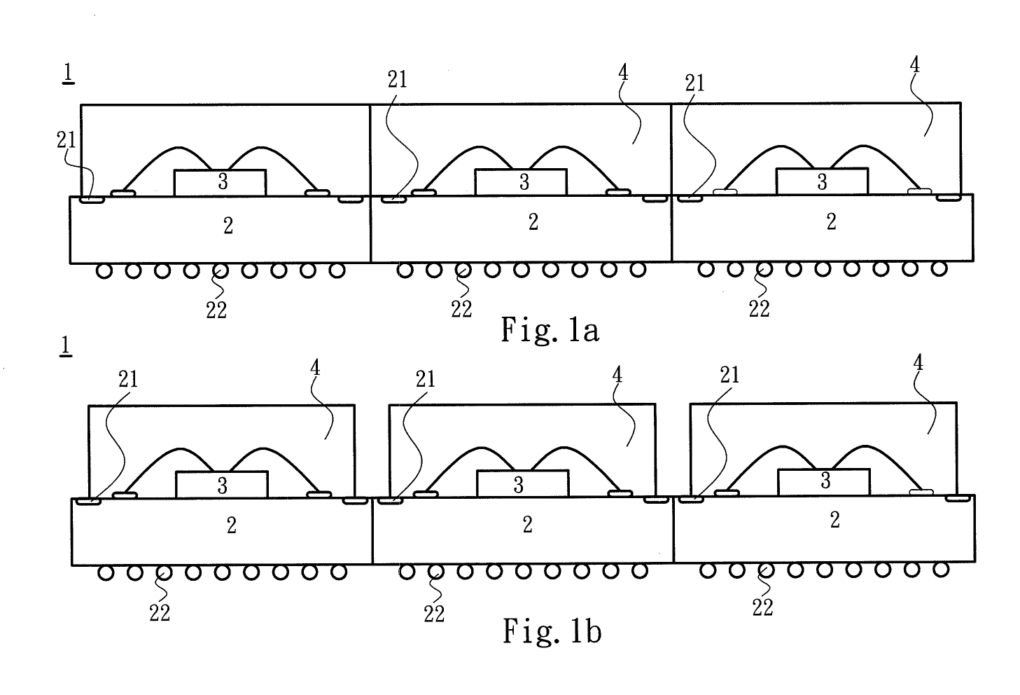

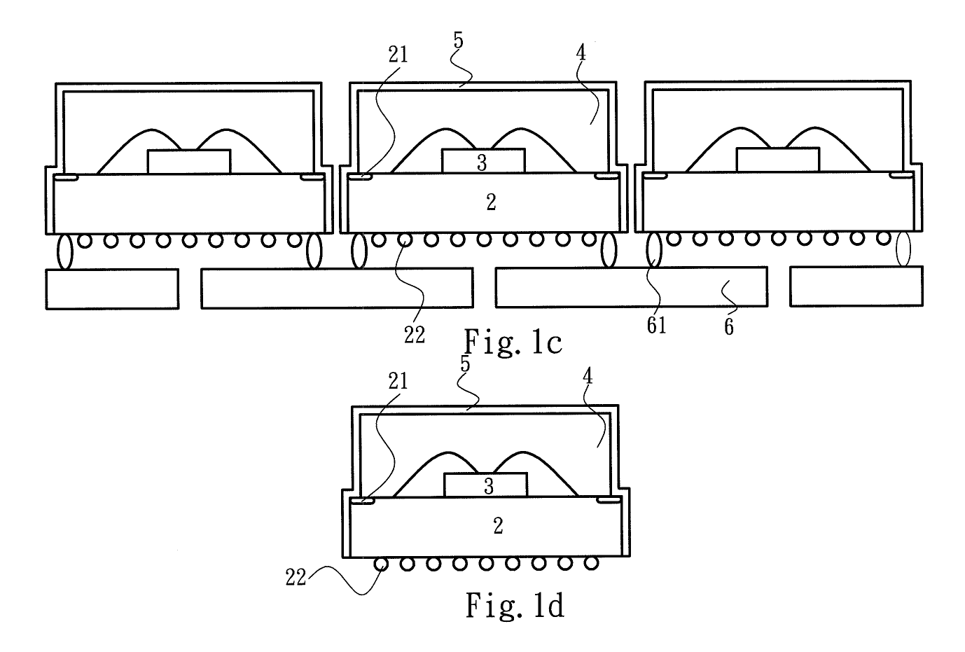

Refer to FIGS. 1a-1d, which are side-view diagrams illustrating a method for manufacturing a chip package according to one embodiment of the present invention. First of all, a chip mounting device 1 having a plurality of chip mounting units 2 arrayed thereon is provided. For example, the chip mounting device 1 may be a package substrate, a flexible substrate or a leadframe. Each chip mounting unit 2 is provided with a ground ring 21 configured on an upper surface of the chip mounting unit 2. Each of chips 3 is respectively mounted on the upper surface of each chip mounting unit 2 and electrically connected to the upper surface of each chip mounting unit 2. The chip 3 may be electrically connected to the chip mounting unit 2 via wire-bonding or flip-chip.

In one embodiment, the ground ring 21 encircles the outer rim of the chip 3 and is electrically connected to a ground pad (not illustrated) of the chip 3 so as for the chip 3 to be grounded. Here, the ground ring 21 may be continuous or discontinuous. The discontinuous ground ring 21 may be formed by dividing the ground ring 21 with green paint or other blocking material so as to increase the binding area and binding strength to the chip 3. The ground ring 21 may be electrically connected to the chip 3 by connecting to the ground pad, thereby partially masked by the chip 3; or electrically connected to the chip 3 via wire bonding, thereby not masked by the chip 3.

As illustrated in FIG. 1a, the ground ring 21 and chip 3 on each chip mounting unit 2 is covered with an encapsulating material 4. The encapsulating material 4 may be common material, such as epoxy, applied in chip package and applied by heating and curing.

Each chip mounting unit 2 may further include a plurality of solder balls 22 mounted to a lower surface of the chip mounting unit 2 by using solder ball placement. The ground ring 21 is electrically connected to the solder balls 22. Here, the ground ring 21 may be electrically connected to the solder balls 22 via a through hole or a blind hole electrically connected with a grounding layer (not illustrated) within the chip mounting unit 2.

Referring to FIG. 1b, the encapsulating material 4 is partially removed so as to expose a part of the ground ring 21. The method for removing the encapsulating material 4 may include without limitations to milling, cutting or sawing.

Referring to FIG. 1c, a conductive film 5 is then formed covering the encapsulating material 4 and the exposed ground ring 21. The formed conductive film 5 is electrically connected with the ground ring 21 and therefore may cope with the external electromagnetic radiation through grounding, resulting in decreased external EMI. Here, the forming method for the conductive film 5 may include without limitations to sputtering, evaporation, electroless plating, electroplating, or coating method. As illustrated, during sputtering or other process for forming the conductive film 5, the chip mounting device 1 may be immobilized with a vacuum suction platform 6 and a sucking disk 61.

The thickness of the conductive film 5 should be enough to shield the chip 3 from external EMI and determined on used material, resistance and desired shielding effect. In one embodiment, the conductive film 5 is made of metal, such as copper, silver, nickel, gold or so on. In addition, in one embodiment, the conductive film 5 may be transparent and made of ITO (Indium Tin Oxide) or so on.

Referring to FIG. 1d, the chip mounting device 1 is then singulated to obtain each separated chip mounting unit 2 for subsequent back-end package process, e.g. testing.

It is noted that procedures for singulation of the chip mounting device 1 and formation of the conductive film 5 are interchangeable. To be specific, in one embodiment, a conductive film 5 is firstly formed, and the chip mounting device is then singulated; in the other embodiment, the chip mounting device 1 is firstly singulated, and a conductive film 5 is then formed.

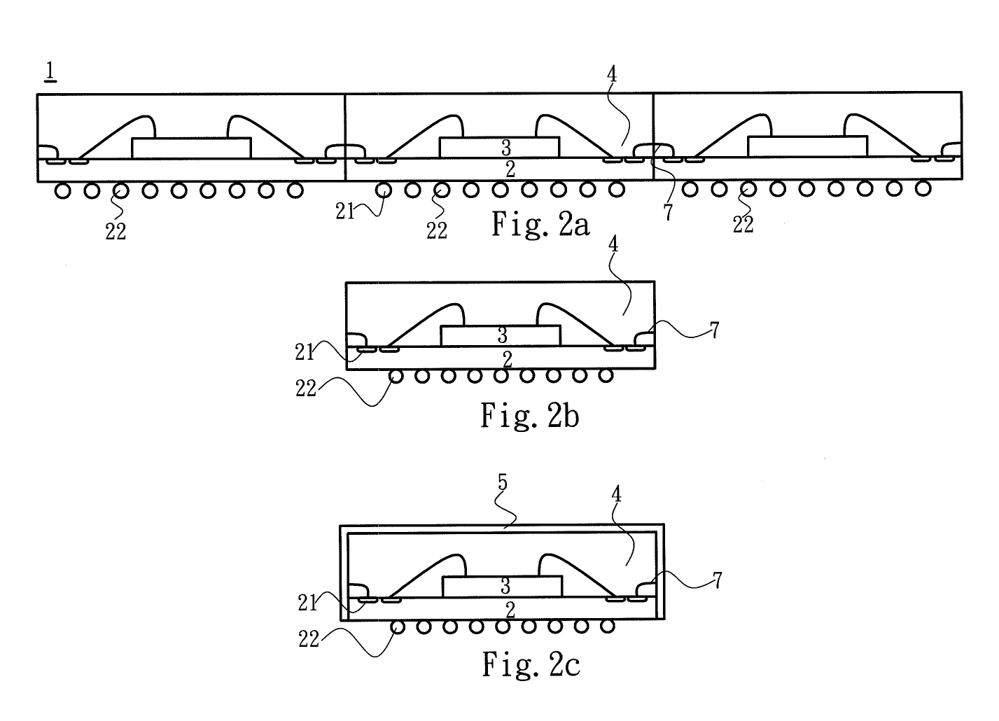

Refer to FIGS. 2a-2c, which are side-view diagrams illustrating a method of manufacturing chip package according to another embodiment of the present invention. In another embodiment, a chip mounting device 1 is provided. Each of chips 3 is respectively mounted on the upper surface of each chip mounting unit 2 and electrically connected to the upper surface of each chip mounting unit 2. A ground ring 21, a wire 7 and chip 3 associated with each chip mounting unit 2 are covered with an encapsulating material 4.

In comparison to FIG. 1a, the ground rings 21 of adjacent chip mounting units 2 are electrically connected to each other via the wire 7. The wire 7 may be electrically connected to the ground ring 21 by arc wire bonding (as illustrated), or the wire 7 is configured on the upper surface of the chip mounting 2 or inside thereof to be electrically connected to the ground ring 21.

Referring to FIG. 2b, the chip mounting device 1 is then singulated to obtain each separated chip mounting unit 2 and expose a part of the wire 7. As illustrated in FIG. 2c, a conductive film 5 is formed to cover the encapsulating material 4 and the exposed wire 7. The detail of this embodiment is the same as that in the above embodiment and is thus abbreviated.

To sum up, the present invention is achieved by exposing a ground ring out of encapsulating material in a direct or indirect way and forming a conductive film electrically connected to the ground ring so as to form an EMI shield and prevent external EMI. In addition, the present invention also massively forms conductive film for package structure for lowering the complexity and cost of manufacturing processes.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. A method for manufacturing chip package including:
providing a chip mounting device having a plurality of chip mounting units arrayed thereon, wherein each chip mounting unit is provided with a ground ring configured on an upper surface of the chip mounting unit;
respectively mounting each chip on the upper surface of each chip mounting unit and electrically connecting the chip to the upper surface of each chip mounting unit;
covering the ground ring and the chip on each chip mounting unit with an encapsulating material;
partially removing the encapsulating material so as to expose a part of the ground ring;
forming a conductive film covering the encapsulating material and the exposed ground ring; and
singulating the chip mounting device to obtain each separated chip mounting unit.

2. The method as claimed in claim 1, wherein the chip is electrically connected to the chip mounting unit via wire-bonding or flip-chip.

3. The method as claimed in claim 1, wherein the chip mounting device includes a package substrate, a flexible substrate or a leadframe.

4. The method as claimed in claim 1, the conductive film is formed by a sputtering, evaporation, electroless plating, electroplating, or coating method.

5. The method as claimed in claim 1, wherein the ground ring is partially masked by the chip.

6. The method as claimed in claim 1, wherein each of the chip mounting unit further includes a plurality of solder balls mounted to a lower surface of the chip mounting unit.

7. The method as claimed in claim 6, wherein the ground ring is electrically connected to the solder balls via a through hole or a blind hole.

8. A method for manufacturing chip package, including:
providing a chip mounting device having a plurality of chip mounting units arrayed thereon, wherein each chip mounting unit is provided with a ground ring configured on an upper surface of the chip mounting unit and the ground rings of adjacent chip mounting units are electrically connected to each other via a wire;
respectively mounting each chip on the upper surface of each chip mounting unit and electrically connecting the chip to the upper surface of each chip mounting unit;
covering the ground ring, the chip and the wire associated with each chip mounting unit with an encapsulating material;
singulating the chip mounting device to obtain each separated chip mounting unit and expose a part of the wire; and
forming a conductive film covering the encapsulating material and the exposed wire.

9. The method as claimed in claim 8, wherein the chip is electrically connected to the chip mounting unit via wire-bonding or flip-chip.

10. The method as claimed in claim 8, wherein the chip mounting device includes a package substrate, a flexible substrate or a leadframe.

11. The method as claimed in claim 8, the conductive film 5 is formed by sputtering, evaporation, electroless plating, electroplating, or coating method.

12. The method as claimed in claim 8, wherein the ground ring is partially masked by the chip.

13. The method as claimed in claim 8, wherein each of the chip mounting unit further includes a plurality of solder balls mounted to a lower surface of the chip mounting unit.

14. The method as claimed in claim 13, wherein the ground ring is electrically connected to the solder balls via a through hole or a blind hole.

15. The method as claimed in claim 8, wherein the wire is electrically connected to the ground ring via arc wire bonding.

16. The method as claimed in claim 8, wherein the wire is configured on the upper surface of the chip mounting or inside thereof.
